(19) United States
(12) Patent Application Publication
(10) Pub. No.: US 2023/0213857 A1
(43) Pub. Date: Jul. 6, 2023

(54) RESIST UNDERLAYER FILM-FORMING COMPOSITION CONTAINING RADICAL TRAPPING AGENT

(71) Applicant: NISSAN CHEMICAL CORPORATION, Tokyo (JP)

(72) Inventors: Satoshi KAMIBAYASHI, Toyama-shi (JP); Takafumi ENDO, Toyama-shi (JP); Yuto HASHIMOTO, Toyama-shi (JP); Yuki ENDO, Toyama-shi (JP); Takahiro KISHIOKA, Toyama-shi (JP); Rikimaru SAKAMOTO, Toyama-shi (JP)

(73) Assignee: NISSAN CHEMICAL CORPORATION, Tokyo (JP)

(21) Appl. No.: 17/417,634

(22) PCT Filed: Feb. 13, 2020
(86) PCT No.: PCT/JP2020/005428

§ 371 Date: Oct. 6, 2022

(30) Foreign Application Priority Data
Feb. 14, 2019 (JP) 2019-024794
Apr. 11, 2019 (JP) 2019-075868

(51) Int. Cl. G03F 7/027; G03F 7/031; G03F 7/32; G03F 7/20; G03F 7/11; G03F 7/38

(52) U.S. Cl. CPC G03F 7/0275; G03F 7/031; G03F 7/322; G03F 7/20; G03F 7/11; G03F 7/38

(57) ABSTRACT

Provided is a resist underlayer film-forming composition that is used in a lithographic process in semiconductor manufacturing and has excellent storage stability. The resist underlayer film-forming composition contains: a polymer having a disulfide bond in a main chain; a radical trapping agent; and a solvent. The radical trapping agent is preferably a compound having a ring structure or a thioether structure. The ring structure is preferably an aromatic ring structure having 6-40 carbon atoms or a 2,2,6,6-tetramethylpiperidine structure.

### TECHNICAL FIELD

The present invention relates to a resist underlayer film-forming composition used in a lithography process in semiconductor manufacturing. The present invention also relates to the application of the resist underlayer film-forming composition to a resist-patterned substrate production method and a semiconductor device manufacturing method.

### BACKGROUND ART

In semiconductor manufacturing, a lithography process, in which a resist underlayer film is provided between a substrate and a resist film to allow the desired shape of resist pattern to be transferred, has widely been known. Patent Literature 1 discloses a lithographic resist underlayer film-forming composition that includes a polymer containing a disulfide bond in the main chain, and a solvent.

### CITATION LIST

### Patent Literature

Patent Literature 1: WO 2009/096340

### SUMMARY OF INVENTION

### Technical Problem

Resist underlayer film-forming compositions are used in lithography processes in the manufacturing of semiconductor devices. In continuous manufacturing of semiconductor devices, the components in such a composition (the state of the composition) are required to remain unchanged (storage stability), even after the lapse of a certain amount of time, in order to ensure smooth supply of the materials in the lithography step in the semiconductor device manufacturing process. In particular, polymers, which are the main components of such a composition, are required to have no change in their molecular weight (for example, weight average molecular weight). However, polymers containing a disulfide bond in the main chain decrease their molecular weight during the storage and are thus problematic in storage stability. An object of the present invention is therefore to solve the problems mentioned above.

### Solution to Problem

The present invention embraces the following.

[1]

A resist underlayer film-forming composition comprising a polymer containing a disulfide bond, a radical trapping agent, and a solvent.

[2]

The resist underlayer film-forming composition according to [1], wherein the polymer is a reaction product of:

a bi- or higher-functional compound (A) having at least one disulfide bond, and

a bi- or higher-functional compound (B) different from compound (A).

[3]

The resist underlayer film-forming composition according to [1], wherein the radical trapping agent is a compound (T) having a ring structure or a thioether structure.

[4]

The resist underlayer film-forming composition according to [3], wherein the ring structure is a C6-C40 aromatic ring structure or a 2,2,6,6-tetramethylpiperidine structure.

[5]

The resist underlayer film-forming composition according to [3], wherein compound (T) contains a hydroxy group, a C1-C10 alkyl group or a C1-C20 alkoxy group.

[6]

The resist underlayer film-forming composition according to [2], wherein bi- or higher-functional compound (B) contains a C6-C40 aromatic ring structure or a heterocyclic structure.

[7]

The resist underlayer film-forming composition according to any one of [1] to [6], further comprising a crosslinking catalyst.

[8]

The resist underlayer film-forming composition according to any one of [1] to [7], further comprising a crosslinking agent.

[9]

A resist underlayer film, which is a calcined product of a coating film comprising the resist underlayer film-forming composition according to any one of [1] to [8].

[10]

A method for producing a resist-patterned substrate for use in manufacturing of a semiconductor device, comprising the steps of:

applying the resist underlayer film-forming composition according to any one of [1] to [8] onto a semiconductor substrate and baking the applied composition to form a resist underlayer film,

applying a resist onto the resist underlayer film and baking the applied resist to form a resist film,

exposing the semiconductor substrate coated with the resist underlayer film and the resist, and

developing the exposed resist film.

[11]

A method for manufacturing a semiconductor device, comprising the steps of:

forming on a semiconductor substrate a resist underlayer film from the resist underlayer film-forming composition according to any one of [1] to [8],

forming a resist film on the resist underlayer film,

exposing the resist film,

developing the exposed resist film into a resist pattern,

etching the resist underlayer film through the resist pattern to form a patterned resist underlayer film, and

processing the semiconductor substrate through the patterned resist underlayer film.

### Advantageous Effects of Invention

The resist underlayer film-forming composition of the present invention suffers little change of the polymer in its weight average molecular weight, even after the lapse of a certain amount of time, thereby attaining excellent storage stability. It permits stable supply of the materials and contributes to smooth manufacturing of semiconductor devices.

### DESCRIPTION OF EMBODIMENTS

### Definition of the Terms

The terms used in the present invention have the following definitions unless otherwise specified.

Examples of the “C1-C10 alkyl group” include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, 2-ethyl-3-methyl-cyclopropyl group, decyl group, undecyl group, dodecyl group, tridecyl group, tetradecyl group, pentadecyl group, hexadecyl group, heptadecyl group, octadecyl group, nonadecyl group and eicodecyl group.

Examples of the “C1-C20 alkoxy groups” include methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, 1-ethyl-2-methyl-n-propoxy group, cyclopentyloxy group, cyclohexyloxy group, norbornyloxy group, adamantyloxy group, adamantanemethyloxy group, adamantaneethyloxy group, tetracyclodecanyloxy group and tricyclodecanyloxy group.

Examples of the “C3-C6 alkenyl group” include 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group and 3-cyclohexenyl group.

Examples of the “C1-C10 alkylene group” include methylene group, ethylene group, n-propylene group, isopropylene group, cyclopropylene group, n-butylene group, isobutylene group, s-butylene group, t-butylene group, cyclobutylene group, 1-methyl-cyclopropylene group, 2-methyl-cyclopropylene group, n-pentylene group, 1-methyl-n-butylene group, 2-methyl-n-butylene group, 3-methyl-n-butylene group, 1,1-dimethyl-n-propylene group, 1,2-dimethyl-n-propylene group, 2,2-dimethyl-n-propylene, 1-ethyl-n-propylene group, cyclopentylene group, 1-methyl-cyclobutylene group, 2-methyl-cyclobutylene group, 3-methyl-cyclobutylene group, 1,2-dimethyl-cyclopropylene group, 2,3-dimethyl-cyclopropylene group, 1-ethyl-cyclopropylene group, 2-ethyl-cyclopropylene group, n-hexylene group, 1-methyl-n-pentylene group, 2-methyl-n-pentylene group, 3-methyl-n-pentylene group, 4-methyl-n-pentylene group, 1,1-dimethyl-n-butylene group, 1,2-dimethyl-n-butylene group, 1,3-dimethyl-n-butylene group, 2,2-dimethyl-n-butylene group, 2,3-dimethyl-n-butylene group, 3,3-dimethyl-n-butylene group, 1-ethyl-n-butylene group, 2-ethyl-n-butylene group, 1,1,2-trimethyl-n-propylene group, 1,2,2-trimethyl-n-propylene group, 1-ethyl-1-methyl-n-propylene group, 1-ethyl-2-methyl-n-propylene group, cyclohexylene group, 1-methyl-cyclopentylene group, 2-methyl-cyclopentylene group, 3-methyl-cyclopentylene group, 1-ethyl-cyclobutylene group, 2-ethyl-cyclobutylene group, 3-ethyl-cyclobutylene group, 1,2-dimethyl-cyclobutylene group, 1,3-dimethyl-cyclobutylene group, 2,2-dimethyl-cyclobutylene group, 2,3-dimethyl-cyclobutylene group, 2,4-dimethyl-cyclobutylene group, 3,3-dimethyl-cyclobutylene group, 1-n-propyl-cyclopropylene group, 2-n-propyl-cyclopropylene group, 1-isopropyl-cyclopropylene group, 2-isopropyl-cyclopropylene group, 1,2,2-trimethyl-cyclopropylene group, 1,2,3-trimethyl-cyclopropylene group, 2,2,3-trimethyl-cyclopropylene group, 1-ethyl-2-methyl-cyclopropylene group, 2-ethyl-1-methyl-cyclopropylene group, 2-ethyl-2-methyl-cyclopropylene group, 2-ethyl-3-methyl-cyclopropylene group, n-heptylene group, n-octylene group, n-nonylene group and n-decanylene group.

Examples of the “C1-C6 alkylthio group” include methylthio group, ethylthio group, propylthio group, butylthio group, pentylthio group and hexylthio group.

Examples of the “halogen atom” include fluorine atom, chlorine atom, bromine atom and iodine atom.

Examples of the “C6-C40 aromatic ring structure” include aromatic ring structures derived from, for example, benzene, naphthalene, anthracene, acenaphthene, fluorene, triphenylene, phenalene, phenanthrene, indene, indane, indacene, pyrene, chrysene, perylene, naphthacene, pentacene, coronene, heptacene, benzo[a]anthracene, dibenzophenanthrene and dibenzo[a,j]anthracene.

The “C6-C40 aromatic ring structure” may be derived from, for example, a “C6-C40 aryl group”. Specific examples of the “C6-C40 aryl group” include phenyl group, o-methylphenyl group, m-methylphenyl group, p-methylphenyl group, o-chlorophenyl group, m-chlorophenyl group, p-chlorophenyl group, o-fluorophenyl group, p-fluorophenyl group, o-methoxyphenyl group, p-methoxyphenyl group, p-nitrophenyl group, p-cyanophenyl group, α-naphthyl group, β-naphthyl group, o-biphenylyl group, m-biphenylyl group, p-biphenylyl group, 1-anthryl group, 2-anthryl group, 9-anthryl group, 1-phenanthryl group, 2-phenanthryl group, 3-phenanthryl group, 4-phenanthryl group and 9-phenanthryl group.

Examples of the “heterocyclic structure” include furan, thiophene, pyrrole, imidazole, pyran, pyridine, pyrimidine, pyrazine, pyrrolidine, piperidine, piperazine, morpholine, indole, purine, quinoline, isoquinoline, quinuclidine, chromene, thianthrene, phenothiazine, phenoxazine, xanthene, acridine, phenazine, carbazole, triazinone, triazinedione and triazinetrione.

The term “functional” is a concept focused on the chemical properties and chemical reactivity of a substance and, when it is used as “functional group”, it reminds of the properties inherent thereto and chemical reactivity thereof. In the present application, the term refers to a reactive substituent capable of bonding to another compound. That is, for example, the term “trifunctional” means that the compound has three reactive substituents. In the present application, the number of functionality is represented by an integer. Specific examples of the reactive substituents include hydroxy groups, epoxy groups, acyl groups, acetyl groups, formyl groups, benzoyl groups, carboxy groups, carbonyl groups, amino groups, imino groups, cyano groups, azo groups, azide groups, thiol groups, sulfo groups and allyl groups.

### Resist Underlayer Film-Forming Composition

A resist underlayer film-forming composition of the present application includes a polymer containing a disulfide bond, preferably a polymer containing a disulfide bond in the main chain, a radical trapping agent, and a solvent.

Details will be described sequentially hereinbelow.

### Polymer Containing a Disulfide Bond

The polymer containing a disulfide bond of the present application may be, for example, a polymer described in WO 2009/096340, or a reaction product described in WO 2019/151471 of a polyfunctional compound having at least one disulfide bond and a polyfunctional compound. The polymers, however, are not limited thereto.

The polymer may be a reaction product of a bifunctional compound (A) having at least one disulfide bond and a bifunctional compound (B) different from compound (A). In this case, the polymer contains a disulfide bond in its main chain.

The polymer may have a repeating unit structure represented by the following formula (1).

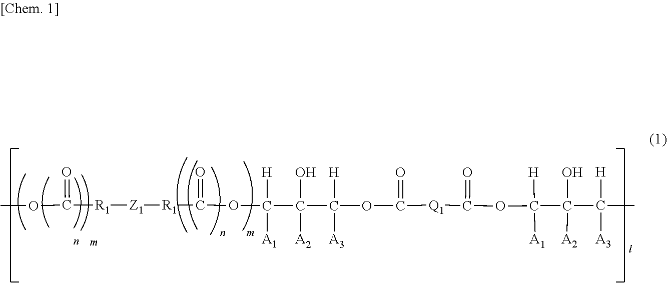

(In formula (1), R₁ denotes a direct bond or a methyl group,

n indicates the number of the repeating unit structure and is an integer of 0 or 1, and

m is an integer of 0 or 1.

Z₁ denotes a group represented by the following formula (2), (3) or (2-1):

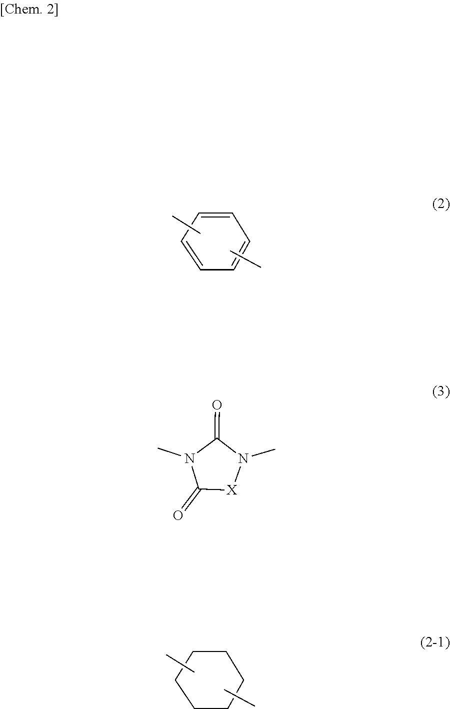

In formula (3) above, X denotes a group represented by the following formula (4), (51) or (6):

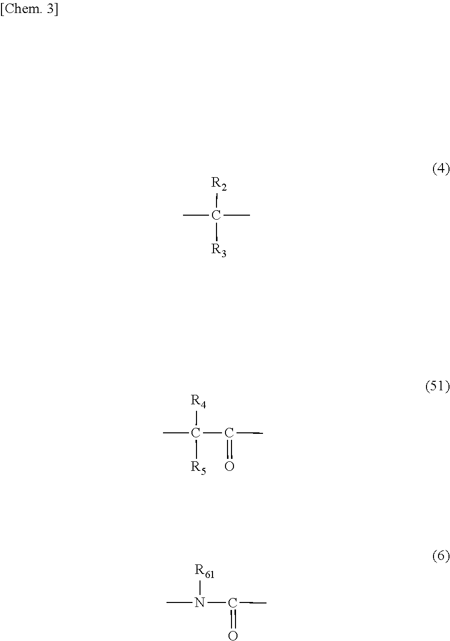

In formulae (4), (51) and (6) above, R₂, R₃, R₄, R₅₁ and R₆₁ each independently denote a hydrogen atom, a C1-C6 alkyl group, a C3-C6 alkenyl group, a benzyl group or a phenyl group,

the phenyl group may be substituted with at least one group selected from the group consisting of C1-C6 alkyl groups, halogen atoms, C1-C6 alkoxy groups, nitro groups, cyano groups and C1-C6 alkylthio groups, and

R₂ and R₃, and R₄ and R₅ may be each bonded together to form a C3-C6 ring.

A₁ to A₆ each independently denote a hydrogen atom, a methyl group or an ethyl group,

Q₁ denotes a C1-C10 alkylene group interrupted by a disulfide bond, and

1 indicates the number of the repeating unit structures and is an integer of 5 to 100.)

Q₁ is preferably a C2-C6 alkylene group interrupted by a disulfide bond.

Examples of the “C3-C6 ring” include cyclopropane, cyclobutane, cyclopentane, cyclopentadiene and cyclohexane.

Formula (1) may be represented by the following formula (5).

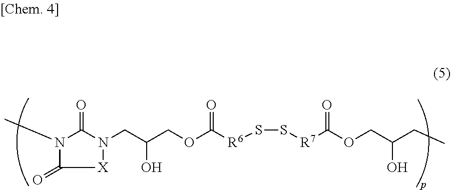

[In formula (5) above, X denotes a group represented by formula (4), (51) or (6) described hereinabove,

R⁶ and R⁷ each independently denote a C1-C3 alkylene group or a direct bond, and

p indicates the number of the repeating unit structures and is an integer of 5 to 100.]

The polymer of the present application is preferably represented by any of (Formula P-6) to (Formula P-8) below.

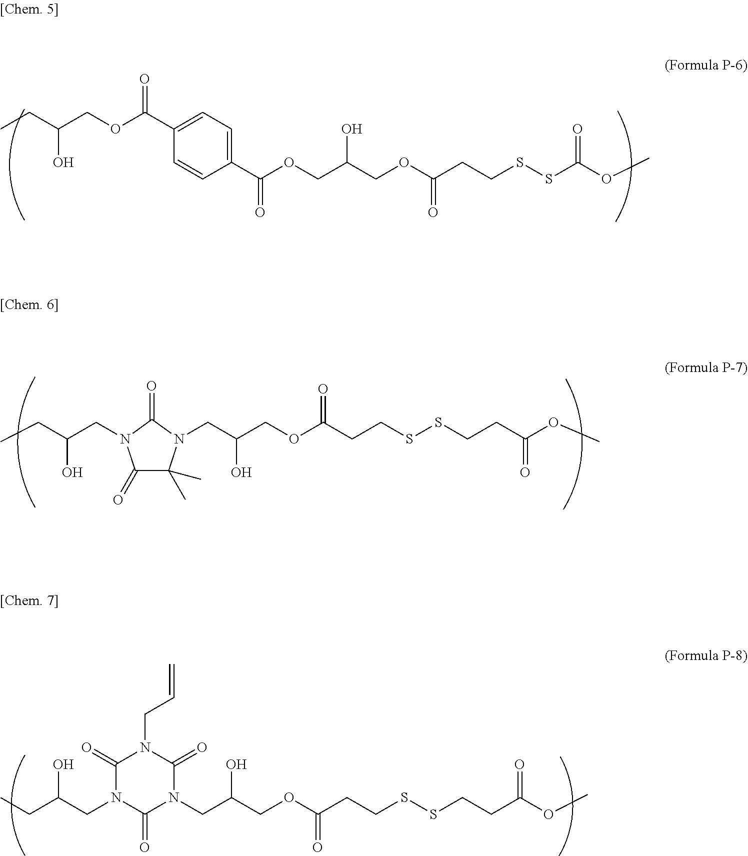

The polymer is preferably a reaction product synthesized by reacting a bi- or higher-functional compound (A) having at least one disulfide bond and a bi- or higher-functional compound (B) different from the compound (A) in accordance with a method that is known per se.

When the bi- or higher-functional compound (A) having at least one disulfide bond and the bi- or higher-functional compound (B) different from compound (A) are both bifunctional, the molar ratio in the reaction is preferably within the range of 0.7:1.0 to 1.0:0.7.

The weight average molecular weight of the polymer ranges, for example, 1,000 to 100,000, or 1,100 to 50,000, or 1,200 to 30,000, or 1,300 to 20,000, or 1,500 to 10,000.

### Bi- or Higher-Functional Compound (A) Having at Least One Disulfide Bond

Bi- or higher-functional compound (A) having at least one disulfide bond may be any compound as long as having two or more functional groups described hereinabove. The compound is preferably bifunctional or trifunctional, and most preferably bifunctional. The functional groups are preferably carboxylic acid groups.

Compound (A) is preferably a dicarboxylic acid containing a disulfide bond.

Compound (A) is more preferably a dicarboxylic acid having a C2 or higher alkylene group interrupted by a disulfide bond. Compound (A) is still more preferably a dicarboxylic acid having a C2-C6 alkylene group interrupted by a disulfide bond.

The dicarboxylic acid containing a disulfide bond is preferably represented by the following formula (1-1).

[Chem. 8]

HOOC—X₁—S—S—X₂—COOH Formula (1-1)

(In formula (1-1), X₁ and X₂ each denote an optionally substituted C1-C10 alkylene group, an optionally substituted C6-C40 arylene group, or a combination thereof.)

The phrase “optionally substituted” means that the C1-C10 alkylene group or the C6-C40 arylene group may be substituted with, for example, a hydroxy group, a halogen atom, a carboxyl group, a nitro group, a cyano group, a methylenedioxy group, an acetoxy group, a methylthio group, an amino group or a C1-C9 alkoxy group in place of part or all of the hydrogen atoms.

Examples of bi- or higher-functional compound (A) having at least one disulfide bond include the following formulae (A-1) to (A-4).

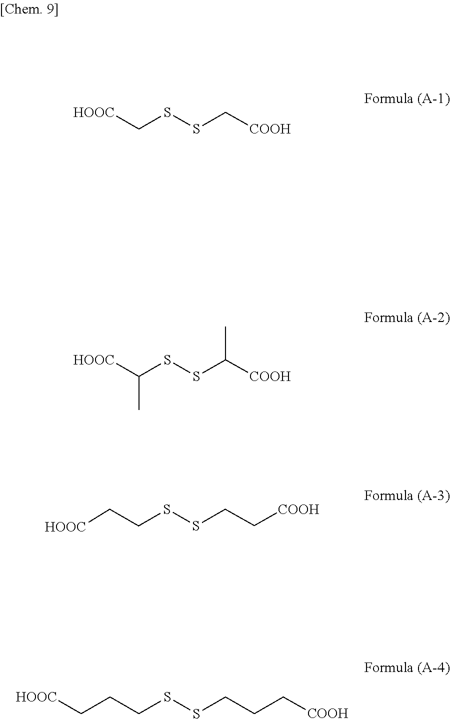

### Bi- or Higher-Functional Compound (B)) (Bifunctional Compound

Bi- or higher-functional compound (B) in the present application is a compound that is different from compound (A). Bi- or higher-functional compound (B) in the present application may be any compound as long as it has two or more functional groups described hereinabove. The compound is preferably bifunctional or trifunctional, and most preferably bifunctional. The functional groups are preferably glycidyl groups. The tri- or higher-functional compounds will be described later.

Bi- or higher-functional compound (B) preferably contains no disulfide bonds.

Bi- or higher-functional compound (B) preferably contains a C6-C40 aromatic ring structure or a heterocyclic structure.

In the heterocyclic structure, the heteroatom is preferably a nitrogen atom and/or an oxygen atom, and the number of carbon atoms is preferably 4 to 24. The heterocyclic structure is preferably triazinone, triazinedione or triazinetrione, and most preferably triazinetrione.

Bifunctional compound (B) is preferably selected from, although not limited to, the following compounds (a) to (z) and (aa). In formula (n), R⁰ denotes a C1-C10 alkylene group.

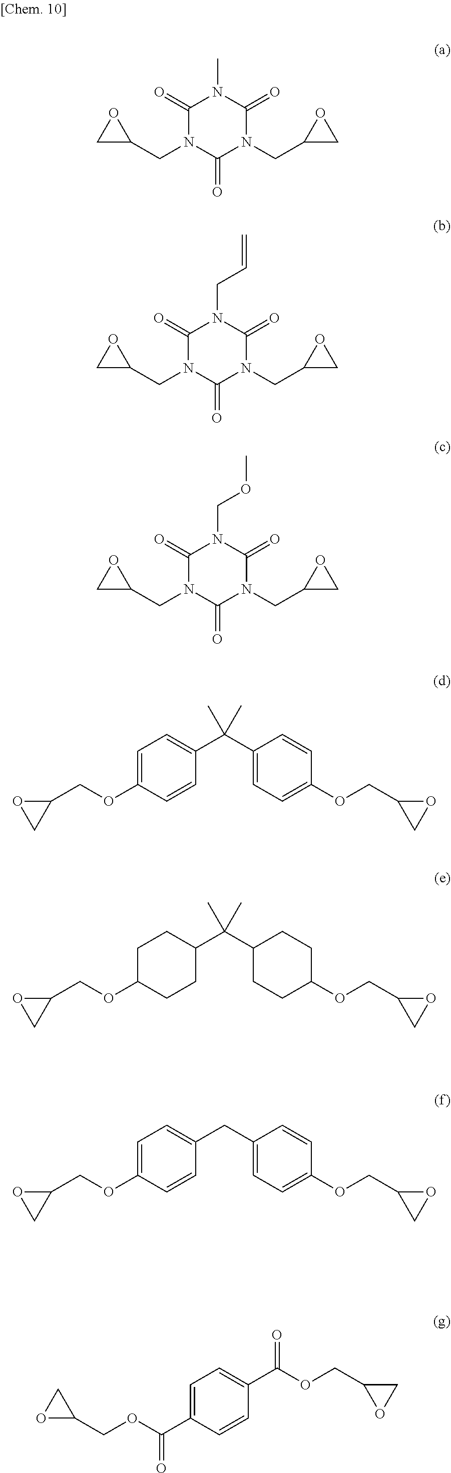

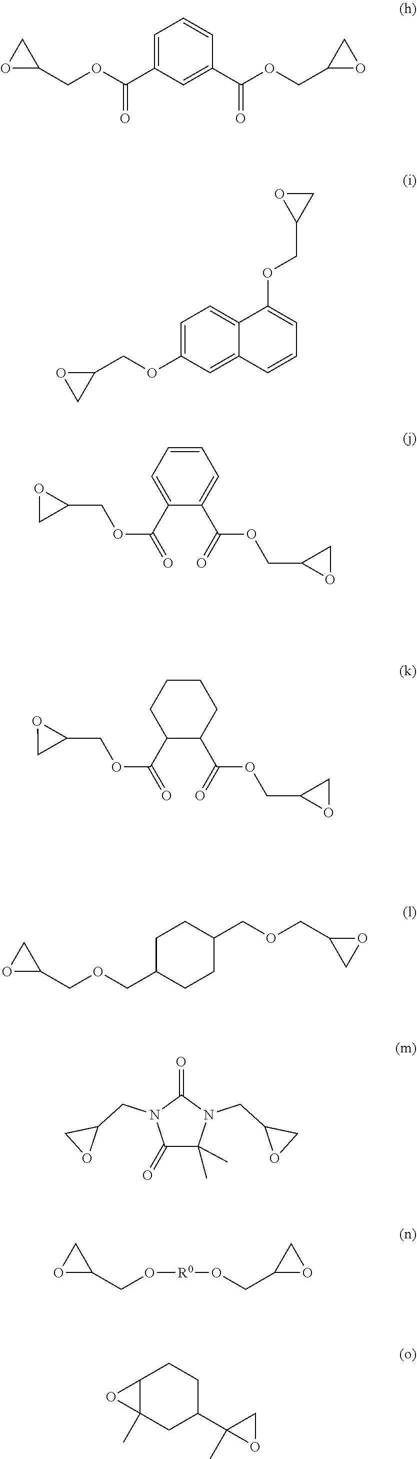

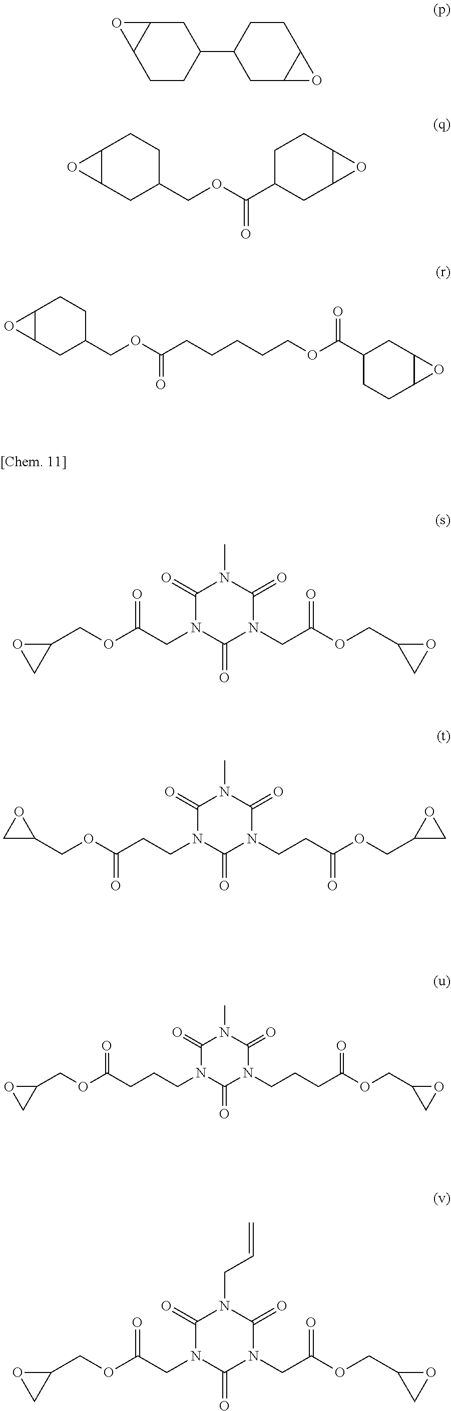

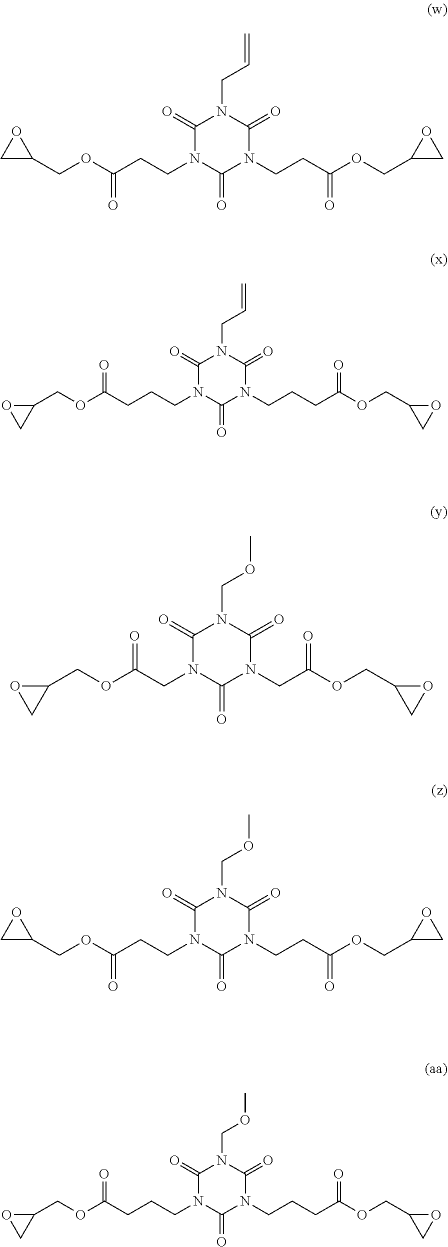 [SMILES: C=CCn1c(=O)n(CCC(=O)OCC2CO2)c(=O)n(CCC(=O)OCC2CO2)c1=O ; C=CCn1c(=O)n(CCCC(=O)OCC2CO2)c(=O)n(CCCC(=O)OCC2CO2)c1=O ; COCn1c(=O)n(CC(=O)OCC2CO2)c(=O)n(CC(=O)OCC2CO2)c1=O ; COCn1c(=O)n(CCC(=O)OCC2CO2)c(=O)n(CCC(=O)OCC2CO2)c1=O ; COCn1c(=O)n(CCCC(=O)OCC2CO2)c(=O)n(CCCC(=O)OCC2CO2)c1=O]

### Bi- or Higher-Functional Compound (B)) (Tri- or Higher-Functional Compound

Bi- or higher-functional compound (B) in the present application may comprise a tri- or higher-functional compound, a tri- to deca-functional compound, a tri- to octa-functional compound, or a tri- to hexa-functional compound. A trifunctional or tetrafunctional compound is preferable.

The tri- or higher-functional compound is preferably a compound containing three or more epoxy groups.

Needless to say, the phrase “containing three or more epoxy groups” means that the compound “contains three or more epoxy groups” in the molecule.

The tri- or higher-functional compound is preferably a compound containing 3 to 10 epoxy groups. Preferably, it is a compound containing 3 to 8 epoxy groups. Preferably, it is a compound containing 3 to 6 epoxy groups. More preferably, it is a compound containing 3 or 4 epoxy groups. Most preferably, it is a compound containing 3 epoxy groups.

Examples of compound (B) containing three or more epoxy groups include glycidyl ether compounds, glycidyl ester compounds, glycidyl amine compounds and glycidyl group-containing isocyanurates.

Examples of the epoxy group-containing compound (B) for use in the present invention include the following formulae (A-1) to (A-15).

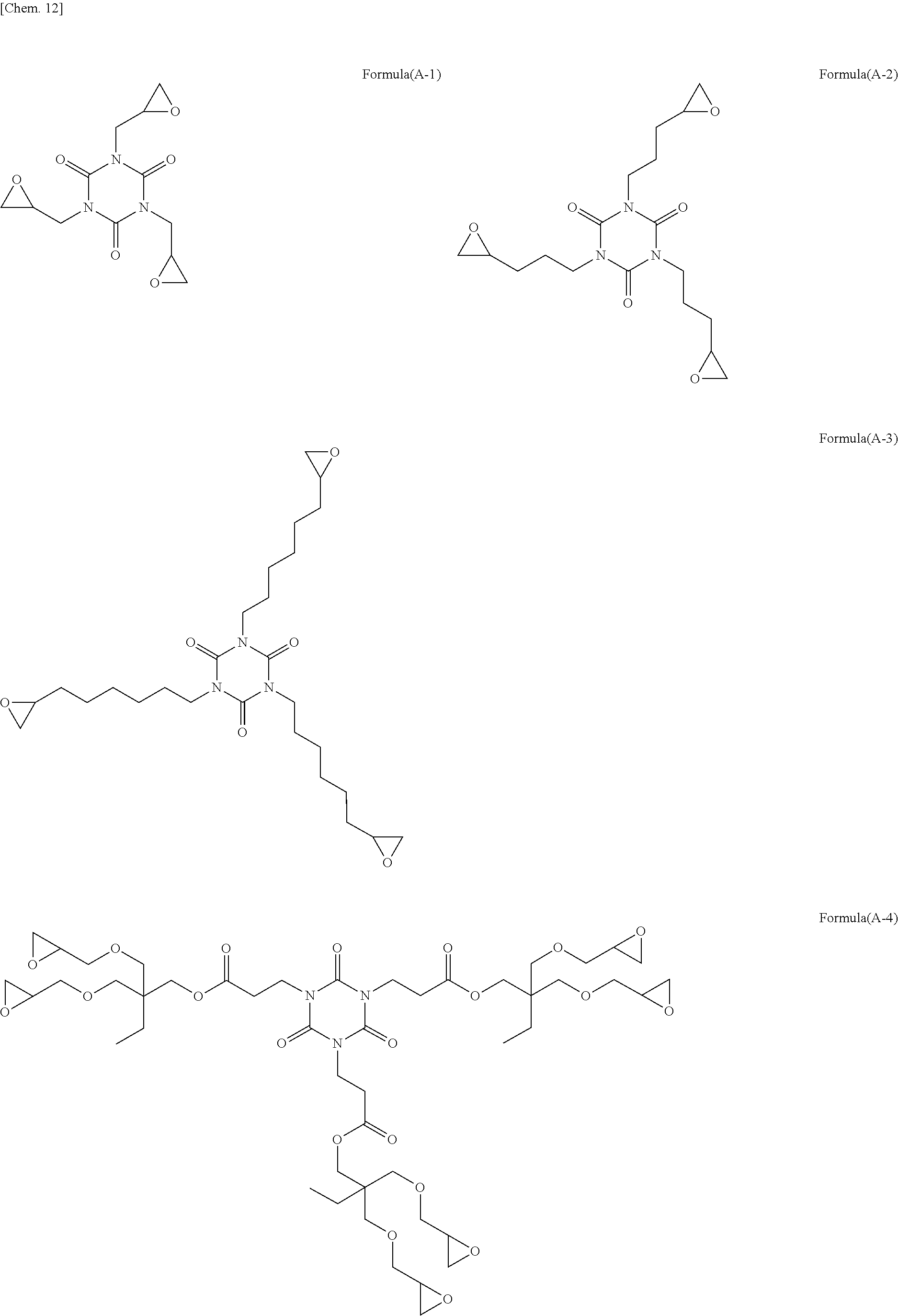

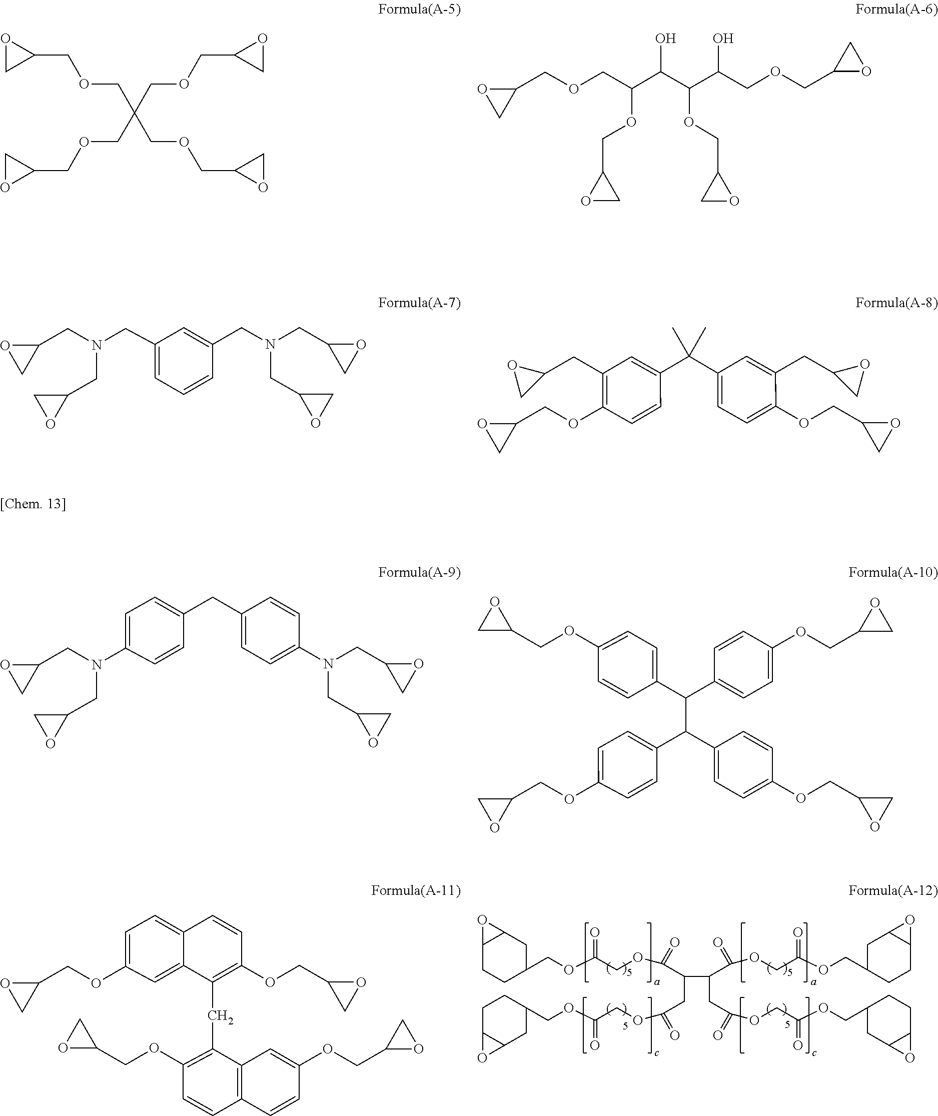

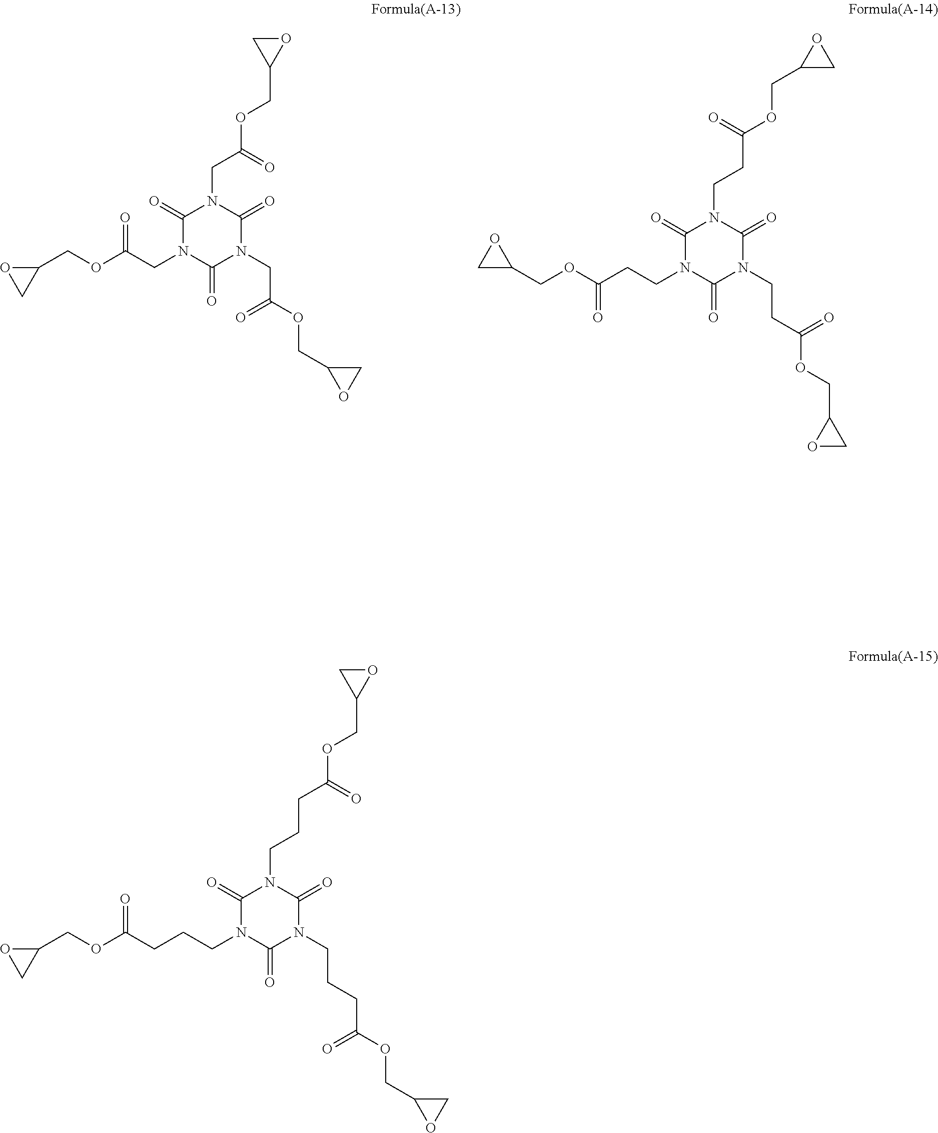 [SMILES: O=C(Cn1c(=O)n(CC(=O)OCC2CO2)c(=O)n(CC(=O)OCC2CO2)c1=O)OCC1CO1 ; O=C(CCn1c(=O)n(CCC(=O)OCC2CO2)c(=O)n(CCC(=O)OCC2CO2)c1=O)OCC1CO1 ; O=C(CCCn1c(=O)n(CCCC(=O)OCC2CO2)c(=O)n(CCCC(=O)OCC2CO2)c1=O)OCC1CO1]

Formula (A-i) is available under the trade names TEPIC-G, TEPIC-S, TEPIC-SS, TEPIC-HP and TEPIC-L (all 1,3,5-tris(2,3-epoxypropyl)isocyanuric acids) manufactured by Nissan Chemical Corporation.

Formula (A-2) is available under the trade name TEPIC-VL manufactured by Nissan Chemical Corporation.

Formula (A-3) is available under the trade name TEPIC-FL manufactured by Nissan Chemical Corporation.

Formula (A-4) is available under the trade name TEPIC-UC manufactured by Nissan Chemical Corporation.

Formula (A-5) is available under the trade name DENACOL EX-411 manufactured by Nagase ChemteX Corporation.

Formula (A-6) is available under the trade name DENACOL EX-521 manufactured by Nagase ChemteX Corporation.

Formula (A-7) is available under the trade name TETRAD-X manufactured by MITSUBISHI GAS CHEMICAL COMPANY, INC.

Formula (A-8) is available under the trade name BATG manufactured by SHOWA DENKO K.K.

Formula (A-9) is available under the trade name YH-434L manufactured by NIPPON STEEL & SUMIKIN CHEMICAL CO., LTD.

Formula (A-10) is available under the trade name TEP-G manufactured by ASAHI YUKIZAI CORPORATION.

Formula (A-11) is available under the trade name EPICLON HP-4700 manufactured by DIC CORPORATION.

Formula (A-12) is available under the trade name EPOLEAD GT401 manufactured by DAICEL CORPORATION, in which a, b, c and d are each 0 or 1, and a+b+c+d=1.

The molar ratio of tri- or higher-functional compound (A) having at least one sulfide bond to tri- or higher-functional compound (B) different from compound (A) is, for example, within the range of 1:0.1-10, preferably 1:1-5, and more preferably 1:3.

The polymer of the present application may be, but is not limited to, a reaction product having a structure of any of the following formulae (P-1) to (P-5).

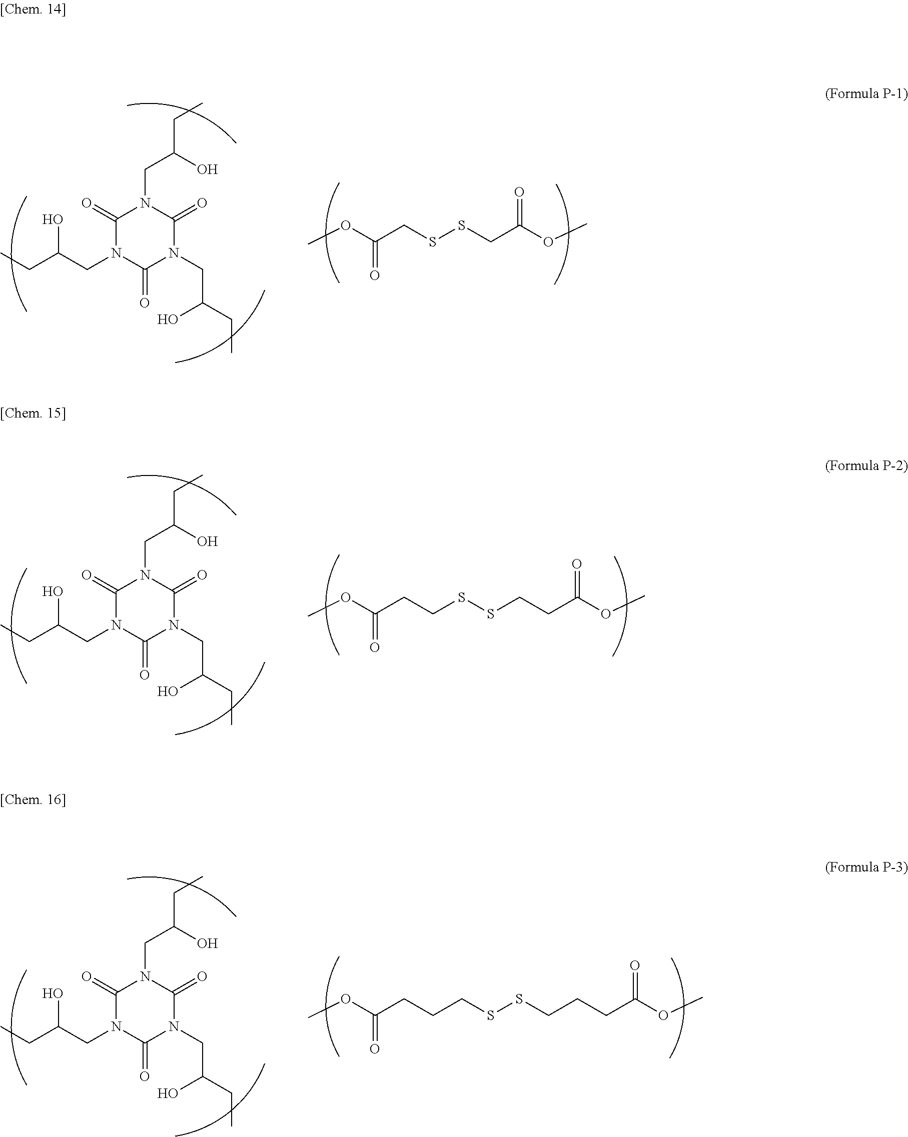

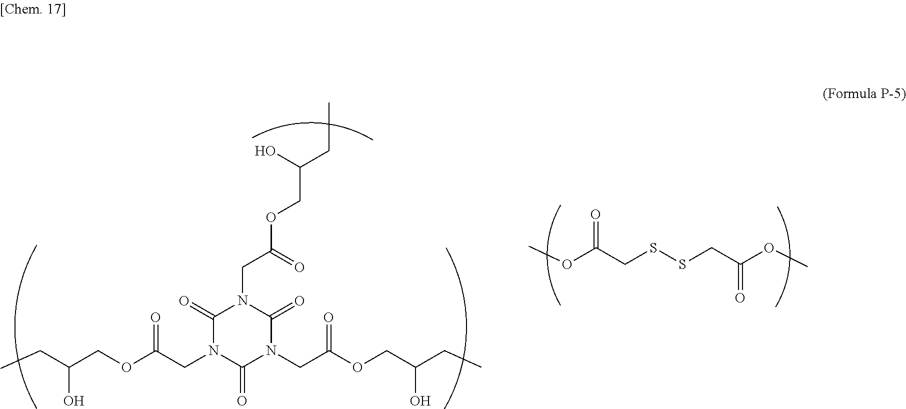

### Solvent

The resist underlayer film-forming composition of the present invention may be produced by dissolving the components described hereinabove into a solvent, preferably an organic solvent, and is used as a uniform solution.

The solvent used in the resist underlayer film-forming composition of the present invention is not particularly limited as long as the solvent can dissolve the compounds or the reaction product described hereinabove. In particular, in view of the fact that the resist underlayer film-forming composition of the present invention is used as a uniform solution and also in consideration of the applicability of the composition, it is recommended to use a solvent generally used in the lithography process in combination.

Examples of the organic solvent include ethylene glycol monomethyl ether, ethylene glycol monoethyl ether, methylcellosolve acetate, ethylcellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide and N,N-dimethylacetamide. The solvent may be used each alone or in combination of two or more.

Of the solvents mentioned above, for example, propylene glycol monomethyl ether, propylene glycol monomethyl ether acetate, ethyl lactate, butyl lactate and cyclohexanone are preferable. In particular, propylene glycol monomethyl ether and propylene glycol monomethyl ether acetate are preferable.

The solid content in the resist underlayer film-forming composition of the present application is usually within the range of 0.1 to 70% by mass, and preferably 0.1 to 60% by mass. The solid content is the proportion of all the components in the protective film-forming composition except the solvent. The proportion of the ring-opened polymer in the solid content ranges 1 to 100% by mass, 1 to 99.9% by mass, 50 to 99.9% by mass, 50 to 95% by mass, and 50 to 90% by mass in order of preference.

### Radical Trapping Agent

The resist underlayer film-forming composition of the present application includes a radical trapping agent. The radical trapping agent may be used each alone or in combination of two or more. The radical trapping agent can probably inhibit the radical cleavage of the disulfide bond in the polymer contained in the resist underlayer film-forming composition of the present application, thereby contributing to the stabilization of the molecular weight of the polymer.

The radical trapping agent is preferably a compound (T) having a ring structure or a thioether structure. Compound (T) preferably contains a hydroxy group, a C1-C10 alkyl group or a C1-C20 alkoxy group.

The radical trapping agent preferably has at least one ring structure. The ring structure is preferably a C6-C40 aromatic ring structure or a 2,2,6,6-tetramethylpiperidine structure.

The resist underlayer film-forming composition of the present application may include, as the radical trapping agent, at least one member selected from, for example, naphthalene derivatives, thioether compounds, hindered amine compounds, ultraviolet absorbers, antioxidants and thermal polymerization inhibitors.

Examples of the naphthalene derivatives include naphthohydroquinone compounds such as naphthohydroquinone sulfonate onium salts. Specific examples include 1,4-dihydroxynaphthalene, 6-amino-2,3-dihydro-5,8-dihydroxynaphthalene-1,4-dione, 6-methylamino-2,3-dihydro-5,8-dihydroxynaphthalene-1,4-dione, 6-ethylamino-2,3-dihydro-5,8-dihydroxynaphthalene-1,4-dione, 6-propylamino-2,3-dihydro-5,8-dihydroxynaphthalene-1,4-dione, 6-butylamino-2,3-dihydro-5,8-dihydroxynaphthalene-1,4-dione, 2-(α,α-dimethyl)naphthalene, 2-(α,α-dimethylbenzyl)naphthalene, 2-t-amylnaphthalene and 2-trimethylsilyl-1,4,5,8,-dimethyl-1,2,3,4,4a,5,8,8a-octahydronaphthalene.

The thioether compounds are not particularly limited as long as, for example, they have at least one thioether group in the molecule. Examples thereof include dimethyl 3,3′-thiodipropionate, dihexyl thiodipropionate, dinonyl thiodipropionate, didecyl thiodipropionate, diundecyl thiodipropionate, didodecyl thiodipropionate, ditridecyl thiodipropionate, ditetradecyl thiodipropionate, dipentadecyl thiodipropionate, hexadecyl thiodipropionate, diheptadecyl thiodipropionate, dioctadecyl thiodipropionate, dihexyl thiodibutyrate, dinonyl thiodibutyrate, didecyl thiodibutyrate, diundecyl thiodibutyrate, didodecyl thiodibutyrate, ditridecyl thiodibutyrate, ditetradecyl thiodibutyrate, dipentadecyl thiodibutyrate, hexadecyl thiodibutyrate, methyl 3-methoxy-2-[2-[cyclopropyl(3-fluorophenylimino)methylthiomethyl]phenyl]acrylate and diheptadecyl thiodibutyrate.

A preferred commercial product is ADK STAB [registered trademark] AO503, which is a thioether antioxidant manufactured by ADEKA CORPORATION.

Examples of the hindered amine compounds include those compounds having a partial structure represented by the following formula (RT1).

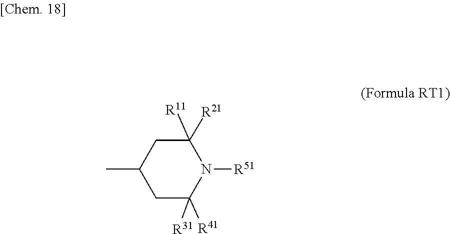

(In formula (RT1), R¹¹ to R⁴¹ each independently denote a hydrogen atom or an alkyl group, and R⁵¹ denotes an alkyl group, an alkoxy group or an aryloxy group.)

The alkyl group is preferably a C1-C3 linear alkyl group, and more preferably a methyl group. The alkyl group contained in the alkoxy group is preferably a C1-C4 linear alkyl group. Examples of the aryl groups contained in the aryloxy groups include phenyl group and naphthyl group.

The molecular weight of the hindered amine compound is preferably not more than 2,000, and more preferably not more than 1,000. In consideration of availability in the market, the molecular weight of the hindered amine compound is preferably within the range of 400 to 700.

Commercial products such as TINUVIN [registered trademark] 123, TINUVIN [registered trademark] 144 and TINUVIN [registered trademark] 152 manufactured by BASF, and ADK STAB [registered trademark] series LA-52, LA-81 and LA-82 manufactured by ADEKA CORPORATION may be suitably used as the hindered amine compounds described above.

Of these, ADK STAB [registered trademark] series LA-81 and LA-82 manufactured by ADEKA CORPORATION are preferable.

Examples of the ultraviolet absorber include salicylate compounds, benzophenone compounds, benzotriazole compounds, cyanoacrylate compounds and nickel chelate compounds.

Examples of the benzotriazole compounds include 2-(2H-benzotriazol-2-yl)-4,6-bis(1-methyl-1-phenylethyl)phenol, 2-(2′-hydroxy-5′-methylphenyl)benzotriazole, 2-(2′-hydroxy-3′-t-butyl-5′-methylphenyl)-5-chlorobenzotriazole and 2-[2-hydroxy-3,5-bis(α,α-dimethylbenzyl)phenyl]-2H-benzotriazole.

As commercially available benzotriazole compounds, TINUVIN [registered trademark] 900, TINUVIN [registered trademark] 928, TINUVIN [registered trademark] P, TINUVIN [registered trademark] 234, TINUVIN [registered trademark]326 and TINUVIN [registered trademark] 329 manufactured by BASF may be used, for example.

Examples of the ultraviolet absorbers which may be used in the present application further include phenyl salicylate, 4-t-butylphenyl salicylate, 2,4-di-t-butylphenyl-3′,5′-di-t-butyl-4′-hydroxybenzoate, 2,4-dihydroxybenzophenone, 2-hydroxy-4-methoxybenzophenone, 2-hydroxy-4-n-octyloxybenzophenone, ethyl-2-cyano-3,3-diphenyl acrylate, 2,2′-hydroxy-4-methoxybenzophenone, nickel dibutyldithiocarbamate, bis(2,2,6,6-tetramethyl-4-piperidine)-sebacate, 4-hydroxy-2,2,6,6-tetramethylpiperidine condensate, bis(2,2,6,6-tetramethyl-4-piperidine) succinate ester and 7-{[4-chloro-6-(diethylamino)-1,3,5-triazin-2-yl]amino}-3-phenylcoumarin.

Examples of the commercially available ultraviolet absorbers include ADK STAB [registered trademark] LA series (such as LA-24, LA-29, LA-31RG, LA-31G, LA-32, LA-36, LA-36RG, LA-46, LA-F70 and 1413) manufactured by ADEKA CORPORATION.

Examples of the thermal polymerization inhibitors include hydroquinone, hydroquinone monomethyl ether, dibutylhydroxytoluene, p-methoxyphenol, di-t-butyl-p-cresol, pyrogallol, phloroglucinol, t-butylcatechol, benzoquinone, 4,4′-thiobis(3-methyl-6-t-butylphenol), 2,2′-methylenebis(4-methyl-6-t-butylphenol), 2-mercaptobenzimidazole, phenothiazine and pentaerythritol tetrakis[3-(3,5-di-tert-butyl-4-hydroxyphenyl)propionate].

Of these, hydroquinone, dibutylhydroxytoluene, pyrogallol and phloroglucinol are preferable.

As commercially available products, ADK STAB [registered trademark] AO series (such as AO-20, AO-30, AO-40, AO-50, AO-50F, AO-60, AO-60G, AO-80 and AO-330), which are phenolic antioxidants manufactured by ADEKA CORPORATION, and IRGANOX [registered trademark] series (such as 1010/FF, 1035/FF, 1076/FD, 1098, 1135, 1141, 1330, 1520 L, 245/FF, 259 and 3114), which are hindered phenolic antioxidants manufactured by BASF, may be used, for example.

Examples of the commercial products further include ADK STAB [registered trademark] PEP series (such as PEP-8, PEP-36, HP-10, 2112, 2112RG, 1178, 1500, C, 135A, 3010 and TPP) which are phosphite antioxidants manufactured by ADEKA CORPORATION.

Of these, ADK STAB (registered trademark) PEP1500 is preferable. In addition to the radical trapping agent mentioned above, the resist underlayer film-forming composition of the present application may include other agents such as an oxidizing agent described in paragraphs 0183 to 0210 of JP 2011-141534 A, and a polymerizable compound having a radical scavenging ability (for example, hindered amine-type and hindered phenol-type polymerizable compounds) described in paragraphs 0103 to 0153 of JP 2011-253174 A, the contents of which are incorporated herein by reference.

Of those mentioned above, the radical trapping agents represented by the following formulae (R-1) to (R-8) are preferable. The radical trapping agents represented by formulae (R-1) to (R-4) are preferable. The radical trapping agents represented by formulae (R-1) to (R-3) are preferable. In particular, the radical trapping agents represented by formulae (R-2) and (R-3) are preferable.

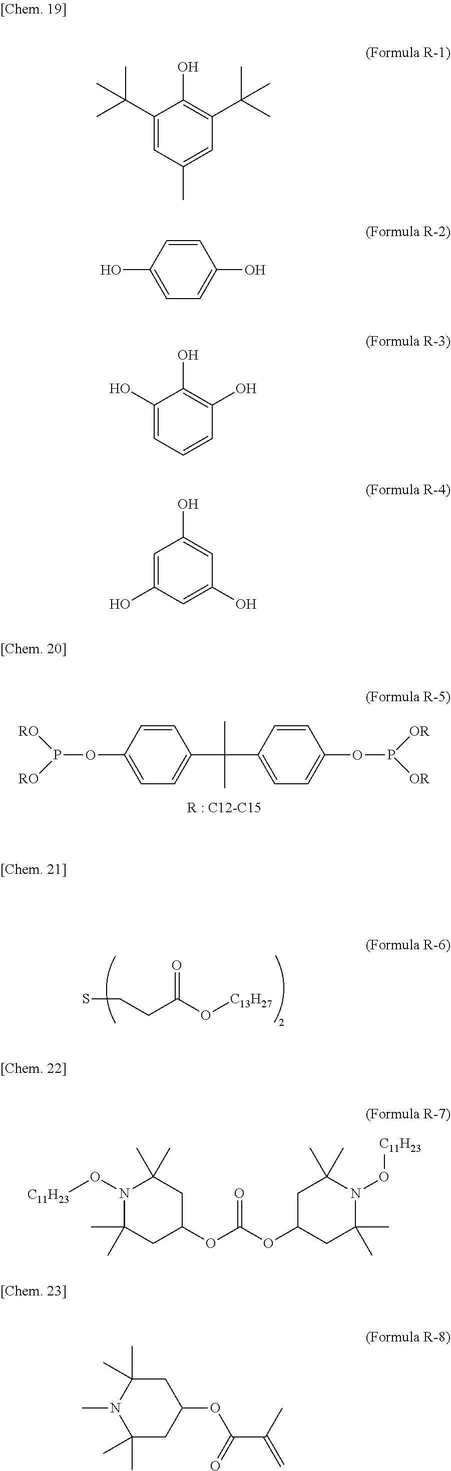

The amount of the radical trapping agent incorporated in the resist underlayer film-forming composition of the present application ranges preferably 0.1 to 20% by mass, more preferably 0.2 to 10% by mass, and particularly preferably 0.4 to 5.0% by mass of the total solid content.

### Crosslinking Catalyst

The resist underlayer film-forming composition of the present invention may include a crosslinking catalyst as an optional component for accelerating the crosslinking reaction. As the crosslinking catalyst, an acidic compound or a compound that generates an acid or a base when heated may be used. As the acidic compound, a sulfonic acid compound or a carboxylic acid compound may be used, and as the compound that generates an acid when heated, a thermal acid generator may be used.

Examples of the sulfonic acid compound and the carboxylic acid compound include p-toluenesulfonic acid, trifluoromethanesulfonic acid, pyridinium trifluoromethanesulfonate, pyridinium-p-toluenesulfonate, pyridinium-4-hydroxybenzenesulfonate, salicylic acid, camphorsulfonic acid, 5-sulfosalicylic acid, 4-chlorobenzenesulfonic acid, 4-hydroxybenzenesulfonic acid, pyridinium-4-hydroxybenzenesulfonic acid, benzenedisulfonic acid, 1-naphthalenesulfonic acid, 4-nitrobenzenesulfonic acid, citric acid, benzoic acid and hydroxybenzoic acid.

Examples of the thermal acid generator include K-PURE [registered trademark] series CXC-1612, CXC-1614, TAG-2172, TAG-2179, TAG-2678 and TAG-2689 (all manufactured by King Industries), and SI-45, SI-60, SI-80, SI-100, SI-110 and SI-150 (all manufactured by SANSHIN CHEMICAL INDUSTRY CO., LTD.).

The crosslinking acid catalyst may be used each alone or in combination of two or more.

When the resist underlayer film-forming composition includes the crosslinking acid catalyst, the content thereof is within the range of 0.0001 to 20% by weight, preferably 0.01 to 15% by weight, and more preferably 0.1 to 10% by mass of the total solid content in the protective film-forming composition.

### Crosslinking Agent

The resist underlayer film-forming composition of the present invention may include a crosslinking agent. Examples of the crosslinking agent include melamine compounds, substituted urea compounds, and polymers thereof. Preferably, the crosslinking agent has at least two crosslinking substituents. It includes methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea and methoxymethylated thiourea. Further, condensates of these compounds may also be used.

The crosslinking agent that is used may be a crosslinking agent having high heat resistance. The crosslinking agent having high heat resistance may be a compound which contains, in the molecule, a crosslinking substituent having an aromatic ring (for example, a benzene ring or a naphthalene ring).

Examples of such compounds include compounds having a partial structure of the following formula (5-1), and polymers or oligomers having a repeating unit of the following formula (5-2).

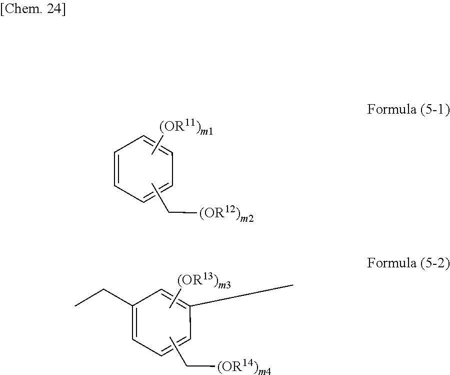

In the above formulae, R¹¹, R¹², R¹³ and R¹⁴ are each a hydrogen atom or a C1-C10 alkyl group. Examples of the alkyl group include those mentioned hereinabove.

m1 meets 1≤m1≤6-m2, m2 meets 1≤m2≤5, m3 meets 1≤m3≤4-m2, and m4 meets 1≤m4≤3.

Examples of the compound, the polymers and the oligomers of formulae (5-1) and (5-2) include the following:

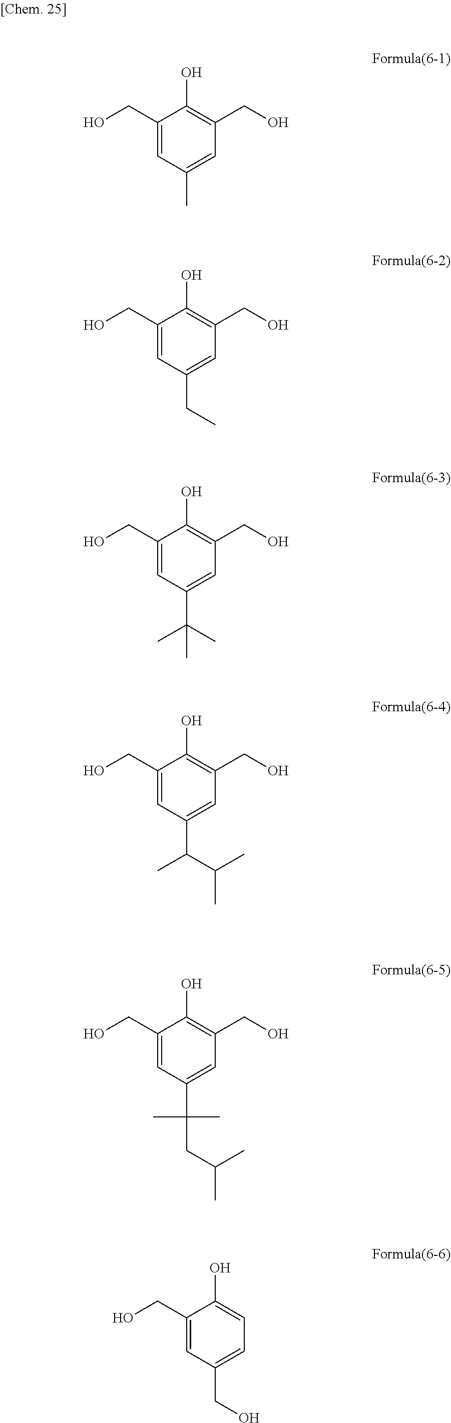 [SMILES: Cc1cc(CO)c(O)c(CO)c1 ; CCc1cc(CO)c(O)c(CO)c1 ; CC(C)(C)c1cc(CO)c(O)c(CO)c1 ; CC(C)C(C)c1cc(CO)c(O)c(CO)c1 ; CC(C)CC(C)(C)c1cc(CO)c(O)c(CO)c1 ; OCc1ccc(O)c(CO)c1]

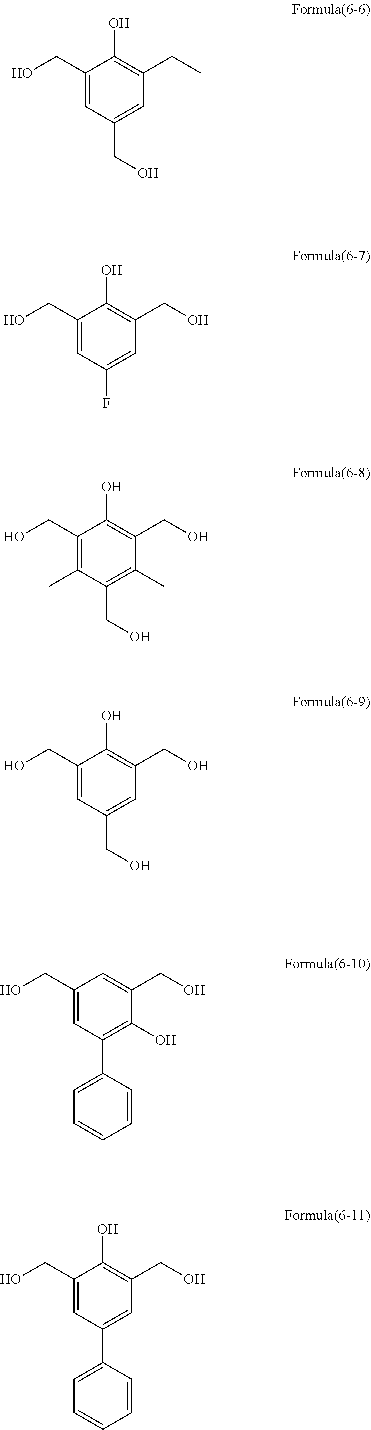 [SMILES: CCc1cc(CO)cc(CO)c1O ; OCc1cc(F)cc(CO)c1O ; Cc1c(CO)c(C)c(CO)c(O)c1CO ; OCc1cc(CO)c(O)c(CO)c1 ; OCc1cc(CO)c(O)c(-c2ccccc2)c1 ; OCc1cc(-c2ccccc2)cc(CO)c1O]

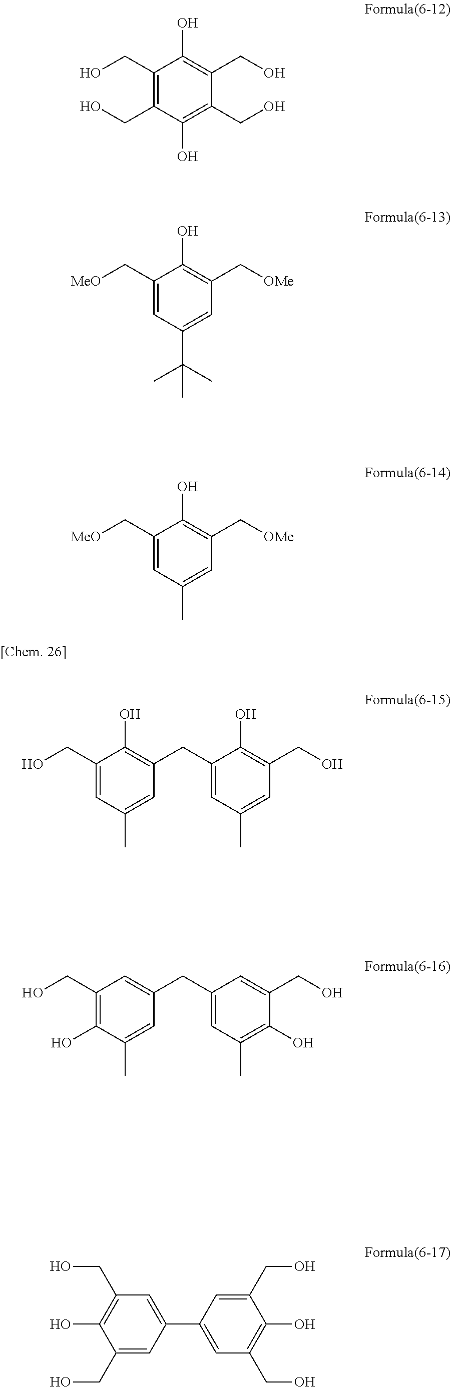 [SMILES: OCc1c(O)c(CO)c(CO)c(O)c1CO ; COCc1cc(C(C)(C)C)cc(COC)c1O ; COCc1cc(C)cc(COC)c1O ; Cc1cc(CO)c(O)c(Cc2cc(C)cc(CO)c2O)c1 ; Cc1cc(Cc2cc(C)c(O)c(CO)c2)cc(CO)c1O ; OCc1cc(-c2cc(CO)c(O)c(CO)c2)cc(CO)c1O]

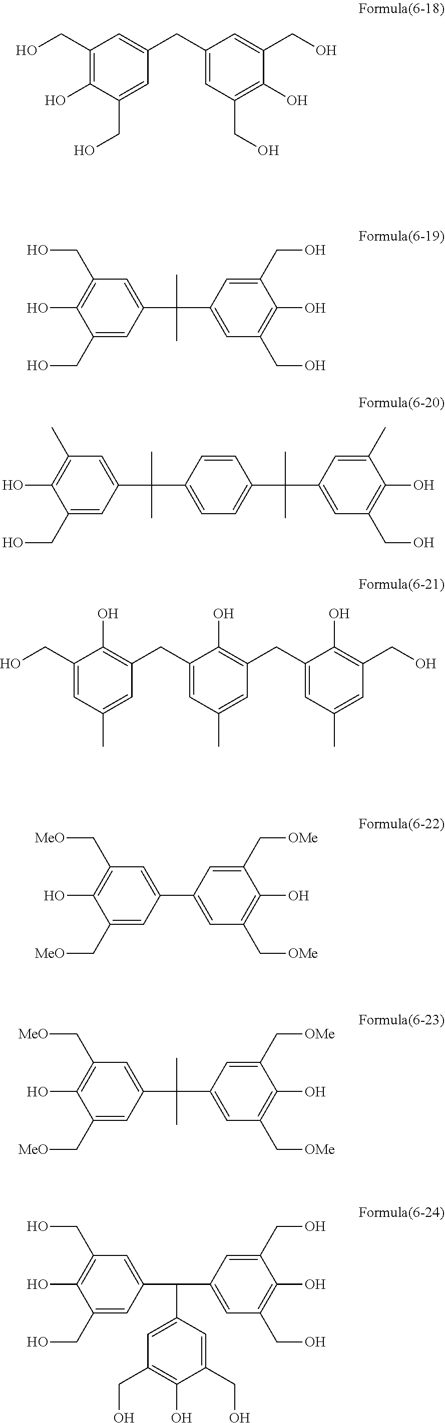

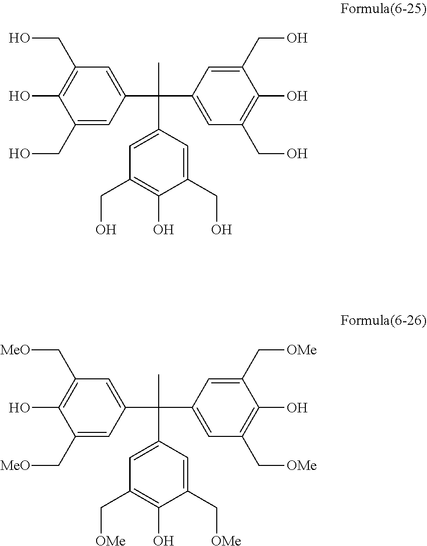 [SMILES: CC(c1cc(CO)c(O)c(CO)c1)(c1cc(CO)c(O)c(CO)c1)c1cc(CO)c(O)c(CO)c1 ; COCc1cc(C(C)(c2cc(COC)c(O)c(COC)c2)c2cc(COC)c(O)c(COC)c2)cc(COC)c1O]

The compounds described above may be obtained as products of ASAHI YUKIZAI CORPORATION and Honshu Chemical Industry Co., Ltd. Of the crosslinking agents illustrated above, for example, the compound of formula (6-22) is available under the trade name TMOM-BP from ASAHI YUKIZAI CORPORATION.

The crosslinking agent may be used each alone or in combination of two or more.

The amount incorporated of the crosslinking agent varies depending on such factors as the coating solvent used, the base substrate used, the required solution viscosity and the required film shape; but may be within the range of 0.001 to 80% by weight, preferably 0.01 to 50% by weight, and more preferably 0.1 to 40% by weight of the total solid content in the protective film-forming composition. The crosslinking agents described above may undergo crosslinking reaction by self-condensation, but can crosslink the polymer of the present invention described above by reacting with any crosslinking substituents present in the polymer.

### Surfactant

The protective film-forming composition of the present invention may include a surfactant as an optional component for enhancing the applicability to a semiconductor substrate. Examples of the surfactant include nonionic surfactants such as polyoxyethylene alkyl ethers including polyoxyethylene lauryl ether, polyoxyethylene stearyl ether, polyoxyethylene cetyl ether and polyoxyethylene oleyl ether, polyoxyethylene alkylaryl ethers including polyoxyethylene octylphenyl ether and polyoxyethylene nonylphenyl ether, polyoxyethylene/polyoxypropylene block copolymers, sorbitan fatty acid esters including sorbitan monolaurate, sorbitan monopalmitate, sorbitan monostearate, sorbitan monooleate, sorbitan trioleate and sorbitan tristearate, and polyoxyethylene sorbitan fatty acid esters including polyoxyethylene sorbitan monolaurate, polyoxyethylene sorbitan monopalmitate, polyoxyethylene sorbitan monostearate, polyoxyethylene sorbitan trioleate and polyoxyethylene sorbitan tristearate, fluorosurfactants such as EFTOP [registered trademark] series EF301, EF303 and EF352 (manufactured by Mitsubishi Materials Electronic Chemicals Co., Ltd.), MEGAFACE [registered trademark] series F171, F173, R-30 and R-40 (manufactured by DIC CORPORATION), Fluorad series FC430 and FC431 (manufactured by Sumitomo 3M Limited), AsahiGuard [registered trademark] AG710, and Surflon [registered trademark] series S-382, SC101, SC102, SC103, SC104, SC105 and SC106 (manufactured by AGC Inc.), and organosiloxane polymer KP341 (manufactured by Shin-Etsu Chemical Co., Ltd.). The surfactant may be used each alone or in combination of two or more. When the protective film-forming composition includes the surfactant, the content thereof is within the range of 0.0001 to 10% by weight, and preferably 0.01 to 5% by weight of the total solid content in the protective film-forming composition.

### Other Components

Other components such as light absorber, rheology modifier and adhesion aid may be added to the protective film-forming composition of the present invention. Rheology modifiers are effective for enhancing the fluidity of the protective film-forming composition. Adhesion aids are effective for enhancing the adhesion between an underlayer film and a semiconductor substrate or a resist.

As the light absorber, commercially available light absorbers may be suitably used, of which the examples are described in “Kougyouyou Shikiso no Gijutsu to Shijou (Technology and Market of Industrial Dyes)” (CMC Publishing Co., Ltd.) and “Senryou Binran (Dye Handbook)” (edited by The Society of Synthetic Organic Chemistry, Japan), such as, for example, C. I. Disperse Yellow 1, 3, 4, 5, 7, 8, 13, 23, 31, 49, 50, 51, 54, 60, 64, 66, 68, 79, 82, 88, 90, 93, 102, 114 and 124; C. I. Disperse Orange 1, 5, 13, 25, 29, 30, 31, 44, 57, 72 and 73; C. I. Disperse Red 1, 5, 7, 13, 17, 19, 43, 50, 54, 58, 65, 72, 73, 88, 117, 137, 143, 199 and 210; C. I. Disperse Violet 43; C. I. Disperse Blue 96; C. I. Fluorescent Brightening Agent 112, 135 and 163; C. I. Solvent Orange 2 and 45; C. I. Solvent Red 1, 3, 8, 23, 24, 25, 27 and 49; C. I. Pigment Green 10; and C. I. Pigment Brown 2.

The light absorber is usually incorporated in a proportion of not more than 10% by mass, and preferably not more than 5% by mass, relative to the total solid content in the protective film-forming composition.

The rheology modifier may be added mainly to enhance the fluidity of the protective film-forming composition and thereby, particularly in the baking step, to increase the uniformity in thickness of the resist underlayer film and to enhance the filling performance of the protective film-forming composition with respect to the inside of holes. Specific examples thereof include phthalic acid derivatives such as dimethyl phthalate, diethyl phthalate, diisobutyl phthalate, dihexyl phthalate and butyl isodecyl phthalate; adipic acid derivatives such as di-n-butyl adipate, diisobutyl adipate, diisooctyl adipate and octyl decyl adipate; maleic acid derivatives such as di-n-butyl maleate, diethyl maleate and dinonyl maleate; oleic acid derivatives such as methyl oleate, butyl oleate and tetrahydrofurfuryl oleate; and stearic acid derivatives such as n-butyl stearate and glyceryl stearate. The rheology modifier is usually added in a proportion of less than 30% by mass relative to the total solid content in the protective film-forming composition.

The adhesion aid may be added mainly to enhance the adhesion between the protective film-forming composition and a substrate or a resist and thereby to prevent the detachment of the resist particularly during development. Specific examples thereof include chlorosilanes such as trimethylchlorosilane, dimethylmethylolchlorosilane, methyldiphenylchlorosilane and chloromethyldimethylchlorosilane; alkoxysilanes such as trimethylmethoxysilane, dimethyldiethoxysilane, methyldimethoxysilane, dimethylmethylolethoxysilane, diphenyldimethoxysilane and phenyltriethoxysilane; silazanes such as hexamethyldisilazane, N,N′-bis(trimethylsilyl)urea, dimethyltrimethylsilylamine and trimethylsilylimidazole; silanes such as methyloltrichlorosilane, γ-chloropropyltrimethoxysilane, γ-aminopropyltriethoxysilane and γ-glycidoxypropyltrimethoxysilane; heterocyclic compounds such as benzotriazole, benzimidazole, indazole, imidazole, 2-mercaptobenzimidazole, 2-mercaptobenzothiazole, 2-mercaptobenzoxazole, urazole, thiouracyl, mercaptoimidazole and mercaptopyrimidine; and urea or thiourea compounds such as 1,1-dimethylurea and 1,3-dimethylurea. The adhesion aid is usually added in a proportion of less than 5% by mass, and preferably less than 2% by mass, relative to the total solid content in the protective film-forming composition.

[Resist Underlayer Film, Method for Producing Resist-Patterned Substrate, and Method for Manufacturing Semiconductor Device]

The following describes a protective film produced using the protective film-forming composition of the present invention, and a method for producing a resist-patterned substrate and a method for manufacturing a semiconductor device each using the protective film-forming composition of the present invention.

A resist-patterned substrate of the present invention may be produced by applying the protective film-forming composition described hereinabove onto a semiconductor substrate and calcining the composition.

Examples of the semiconductor substrates to which the protective film-forming composition of the present invention is applied include silicon wafers, germanium wafers, and compound semiconductor wafers such as gallium arsenide, indium phosphide, gallium nitride, indium nitride and aluminum nitride.

The semiconductor substrate that is used may have an inorganic film on its surface. For example, such an inorganic film is formed by ALD (atomic layer deposition), CVD (chemical vapor deposition), reactive sputtering, ion plating, vacuum deposition or spin coating (spin on glass: SOG). Examples of the inorganic film include polysilicon films, silicon oxide films, silicon nitride films, BPSG (boro-phospho silicate glass) films, titanium nitride films, titanium oxynitride films, tungsten nitride films, gallium nitride films and gallium arsenide films.

The protective film-forming composition of the present invention is applied onto such a semiconductor substrate with an appropriate applicator such as a spinner or a coater. Thereafter, the composition is baked with a heating device such as a hot plate to form a protective film. The baking conditions are appropriately selected from baking temperatures of 100° C. to 400° C. and amounts of baking time of 0.3 minutes to 60 minutes. Preferably, the baking temperature is within the range of 120° C. to 350° C. and the baking time ranges 0.5 minutes to 30 minutes. More preferably, the baking temperature is within the range of 150° C. to 300° C. and the baking time ranges 0.8 minutes to 10 minutes. The thickness of the protective film formed is, for example, within the range of 0.001 μm to 10 μm, preferably 0.002 μm to 1 μm, and more preferably 0.005 μm to 0.5 μm. If the baking temperature is lower than the range described above, the composition is sometimes crosslinked insufficiently and may give a protective film that is poorly resistant to a resist solvent or a basic aqueous hydrogen peroxide solution. If, on the other hand, the baking temperature is higher than the above range, the protective film may be decomposed by heat.

Exposure is performed using, for example, i-line radiation, KrF excimer laser beam, ArF excimer laser beam, EUV (extreme ultraviolet ray) or EB (electron beam) through a mask (a reticle) designed to form a predetermined pattern. An alkaline developer is used for the development, and the conditions are appropriately selected from development temperatures of 5° C. to 50° C. and amounts of development time of 10 seconds to 300 seconds. Examples of the alkaline developer include aqueous solutions of alkalis such as inorganic alkalis including sodium hydroxide, potassium hydroxide, sodium carbonate, sodium silicate, sodium metasilicate and aqueous ammonia, primary amines including ethylamine and n-propylamine, secondary amines including diethylamine and di-n-butylamine, tertiary amines including triethylamine and methyldiethylamine, alcohol amines including dimethylethanolamine and triethanolamine, quaternary ammonium salts including tetramethylammonium hydroxide, tetraethylammonium hydroxide and choline, and cyclic amines including pyrrole and piperidine. Appropriate amounts of alcohol such as isopropyl alcohol and surfactant such as nonionic surfactants may be added to the aqueous alkali solutions described above. Of the developers described above, quaternary ammonium salts are preferable, and tetramethylammonium hydroxide and choline are more preferable. Additional components such as surfactant may be added to the developer. An organic solvent such as butyl acetate may be used in place of the alkali developer to develop portions of the photoresist that remain low in alkali dissolution rate.

Next, the protective film is dry-etched using the thus-formed resist pattern as a mask. When the inorganic film described above is present on the surface of the semiconductor substrate used, the etching process exposes the surface of the inorganic film. When there is no inorganic film on the surface of the semiconductor substrate used, the etching process exposes the surface of the semiconductor substrate.

Further, the semiconductor substrate is wet-etched with a semiconductor wet etchant through the dry-etched protective film (and also through the resist pattern when the resist pattern remains on the protective film) as a mask, thereby forming a desired pattern.

### EXAMPLES

The present invention will be explained in more detail by presenting Synthetic Examples and Examples. However, it should be construed that the scope of the present invention is not limited to such examples.

The weight average molecular weight shown in the present specification is the result measured by gel permeation chromatography (hereinafter, abbreviated as GPC). The measurement was performed using a GPC device manufactured by TOSOH CORPORATION under the following measurement conditions.

GPC columns: Shodex [registered trademark]/Asahipak [registered trademark](SHOWA DENKO K.K.)

Column temperature: 40° C.

Solvent: N,N-dimethylformamide (DMF)

Flow rate: 0.6 ml/min

Standard sample: Polystyrene (TOSOH CORPORATION)

### Synthetic Example 1

In a reaction flask, 43.86 g of diglycidyl terephthalate ester (product name: DENACOL EX-711, manufactured by Nagase ChemteX Corporation), 33.34 g of 3,3′-dithiopropionic acid, 2.80 g of ethyltriphenylphosphonium bromide and 320.00 g of propylene glycol monomethyl ether were stirred in a nitrogen atmosphere for 24 hours while performing heating at 100° C. The resultant reaction product corresponded to (Formula P-6), and the weight average molecular weight determined by GPC in terms of the polystyrene was 5,100.

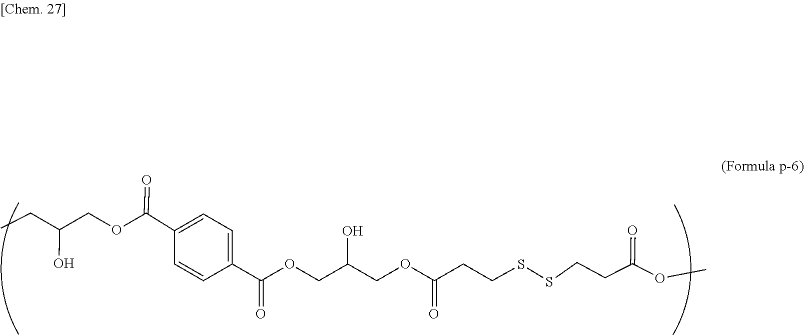

### Synthetic Example 2

In a reaction flask, 131.59 g of 5,5-dimethylhydantoin diglycidyl (product name: DG-DMH, manufactured by SHIKOKU CHEMICALS CORPORATION, 30% solution in propylene glycol monoethyl ether), 37.26 g of 3,3′-dithiopropionic acid, 3.13 g of ethyltriphenylphosphonium bromide and 28.07 g of propylene glycol monomethyl ether were stirred in a nitrogen atmosphere for 24 hours while performing heating at 100° C. The resultant reaction product corresponded to (Formula P-7), and the weight average molecular weight determined by GPC in terms of the polystyrene was 3,530.

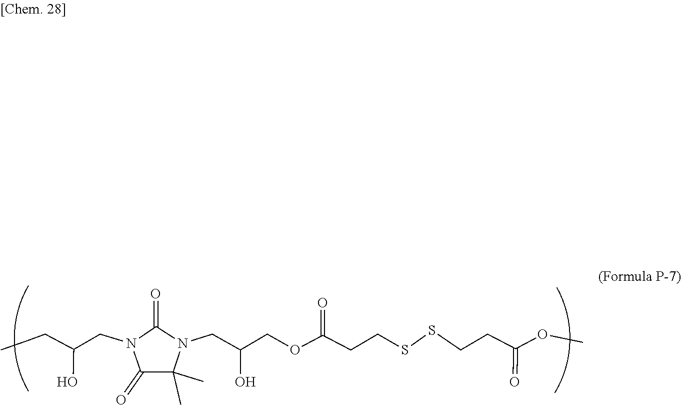

### Example 1

A solution was prepared by adding 83.526 g of propylene glycol monomethyl ether, 9.900 g of propylene glycol monomethyl ether acetate and 0.009 g of dibutylhydroxytoluene (the compound of formula (R-1)) to 5.584 g of a propylene glycol monomethyl ether solution containing 0.990 g of the reaction product from Synthetic Example 1.

### Example 2

A solution was prepared by adding 83.526 g of propylene glycol monomethyl ether, 9.900 g of propylene glycol monomethyl ether acetate and 0.009 g of hydroquinone (the compound of formula (R-2)) to 5.584 g of a propylene glycol monomethyl ether solution containing 0.990 g of the reaction product from Synthetic Example 1.

### Example 3

A solution was prepared by adding 83.526 g of propylene glycol monomethyl ether, 9.900 g of propylene glycol monomethyl ether acetate and 0.009 g of pyrogallol (1,2,3-trihydroxybenzene) (the compound of formula (R-3)) to 5.584 g of a propylene glycol monomethyl ether solution containing 0.990 g of the reaction product from Synthetic Example 1.

### Example 4

A solution was prepared by adding 83.526 g of propylene glycol monomethyl ether, 9.900 g of propylene glycol monomethyl ether acetate and 0.009 g of dibutylhydroxytoluene (the compound of formula (R-1)) to 5.584 g of a propylene glycol monomethyl ether solution containing 0.990 g of the reaction product from Synthetic Example 2.

### Example 5

A solution was prepared by adding 83.526 g of propylene glycol monomethyl ether, 9.900 g of propylene glycol monomethyl ether acetate and 0.009 g of hydroquinone (the compound of formula (R-2)) to 5.584 g of a propylene glycol monomethyl ether solution containing 0.990 g of the reaction product from Synthetic Example 2.

### Example 6

A solution was prepared by adding 83.526 g of propylene glycol monomethyl ether, 9.900 g of propylene glycol monomethyl ether acetate and 0.009 g of pyrogallol (1,2,3-trihydroxybenzene) (the compound of formula (R-3)) to 5.584 g of a propylene glycol monomethyl ether solution containing 0.990 g of the reaction product from Synthetic Example 2.

### Example 7

A solution was prepared by adding 83.526 g of propylene glycol monomethyl ether, 9.900 g of propylene glycol monomethyl ether acetate and 0.009 g of dibutylhydroxytoluene (the compound of formula (R-1)) to 5.584 g of a propylene glycol monomethyl ether solution containing 0.990 g of a reaction product (corresponding to (Formula P-8) and having a weight average molecular weight determined by GPC in terms of the polystyrene of 8,900) obtained by the method described in Synthetic Example 1 of WO 2009/096340 A1.

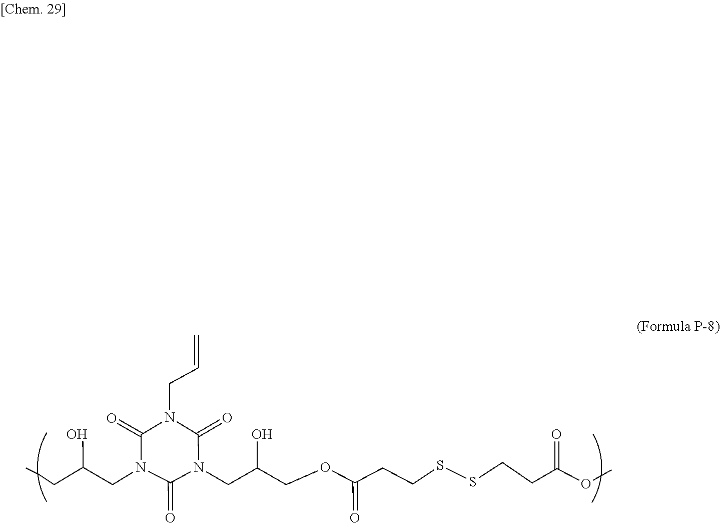

### Example 8

A solution was prepared by adding 83.526 g of propylene glycol monomethyl ether, 9.900 g of propylene glycol monomethyl ether acetate and 0.009 g of hydroquinone (the compound of formula (R-2)) to 5.584 g of a propylene glycol monomethyl ether solution containing 0.990 g of a reaction product (corresponding to (Formula P-8) and having a weight average molecular weight determined by GPC in terms of the polystyrene of 8,900) obtained by the method described in Synthetic Example 1 of WO 2009/096340 A1.

### Example 9

A solution was prepared by adding 83.526 g of propylene glycol monomethyl ether, 9.900 g of propylene glycol monomethyl ether acetate and 0.009 g of pyrogallol (1,2,3-trihydroxybenzene) (the compound of formula (R-3)) to 5.584 g of a propylene glycol monomethyl ether solution containing 0.990 g of a reaction product (corresponding to (Formula P-8) and having a weight average molecular weight determined by GPC in terms of the polystyrene of 8,900) obtained by the method described in Synthetic Example 1 of WO 2009/096340 A1.

### Example 10

A solution was prepared by adding 83.526 g of propylene glycol monomethyl ether, 9.900 g of propylene glycol monomethyl ether acetate and 0.009 g of ADK STAB [registered trademark] 1500 (ADEKA CORPORATION) (the compound of formula (R-5)) to 5.584 g of a propylene glycol monomethyl ether solution containing 0.990 g of a reaction product (corresponding to (Formula P-8) and having a weight average molecular weight determined by GPC in terms of the polystyrene of 8,900) obtained by the method described in Synthetic Example 1 of WO 2009/096340 A1.

### Example 11

A solution was prepared by adding 83.526 g of propylene glycol monomethyl ether, 9.900 g of propylene glycol monomethyl ether acetate and 0.009 g of ADK STAB [registered trademark] AO503 (ADEKA CORPORATION) (the compound of formula (R-6)) to 5.584 g of a propylene glycol monomethyl ether solution containing 0.990 g of a reaction product (corresponding to (Formula P-8) and having a weight average molecular weight determined by GPC in terms of the polystyrene of 8,900) obtained by the method described in Synthetic Example 1 of WO 2009/096340 A1.

### Example 12

A solution was prepared by adding 83.526 g of propylene glycol monomethyl ether, 9.900 g of propylene glycol monomethyl ether acetate and 0.009 g of ADK STAB [registered trademark] LA-81 (ADEKA CORPORATION) (the compound of formula (R-7)) to 5.584 g of a propylene glycol monomethyl ether solution containing 0.990 g of a reaction product (corresponding to (Formula P-8) and having a weight average molecular weight determined by GPC in terms of the polystyrene of 8,900) obtained by the method described in Synthetic Example 1 of WO 2009/096340 A1.

### Example 13

A solution was prepared by adding 83.526 g of propylene glycol monomethyl ether, 9.900 g of propylene glycol monomethyl ether acetate and 0.009 g of ADK STAB [registered trademark] LA-82 (ADEKA CORPORATION) (the compound of formula (R-8)) to 5.584 g of a propylene glycol monomethyl ether solution containing 0.990 g of a reaction product (corresponding to (Formula P-8) and having a weight average molecular weight determined by GPC in terms of the polystyrene of 8,900) obtained by the method described in Synthetic Example 1 of WO 2009/096340 A1.

### Comparative Example 1

A solution was prepared by adding 85.460 g of propylene glycol monomethyl ether and 9.900 g of propylene glycol monomethyl ether acetate to 5.640 g of a propylene glycol monomethyl ether solution containing 1.000 g of the reaction product obtained by the method of Synthetic Example 1.

### Comparative Example 2

A solution was prepared by adding 85.460 g of propylene glycol monomethyl ether and 9.900 g of propylene glycol monomethyl ether acetate to 5.640 g of a propylene glycol monomethyl ether solution containing 1.000 g of the reaction product obtained by the method of Synthetic Example 2.

### Comparative Example 3

A solution was prepared by adding 85.460 g of propylene glycol monomethyl ether and 9.900 g of propylene glycol monomethyl ether acetate to 5.640 g of a propylene glycol monomethyl ether solution containing 1.000 g of a reaction product (corresponding to (Formula P-8) and having a weight average molecular weight determined by GPC in terms of the polystyrene of 8,900) obtained by the method described in Synthetic Example 1 of WO 2009/096340 A1.

### Measurement of Molecular Weight by GPC

The solutions prepared in Examples 1 to 13 and Comparative Examples 1 to 3 were each reacted under nitrogen in an evaporation flask at 100° C. for 6 hours and then analyzed by GPC. Table 1 below shows the initial molecular weight and the molecular weight after the reaction. From the results, it is revealed that the resist underlayer film-forming compositions containing the radical trapping agent of the present invention exhibited improved stability as compared to the resist underlayer film-forming compositions containing no radical trapping agent.

TABLE 1

| | Initial weight average | Weight average molecular weight |
|---|---|---|
| Sample | molecular weight | after 6 hours at 100° C. |
| Example 1 | 5500 | 5440 |
| Example 2 | 5650 | 5700 |
| Example 3 | 5500 | 5400 |
| Comparative | 5100 | 3110 |
| Example 1 | | |

TABLE 2

| | Initial weight average | Weight average molecular weight |
|---|---|---|
| Sample | molecular weight | after 6 hours at 100° C. |
| Example 4 | 3830 | 3740 |
| Example 5 | 3900 | 3960 |
| Example 6 | 3800 | 3750 |
| Comparative | 3530 | 2080 |
| Example 2 | | |

TABLE 3

| | Initial weight average | Weight average molecular weight |
|---|---|---|
| Sample | molecular weight | after 6 hours at 100° C. |
| Example 7 | 8670 | 6370 |
| Example 8 | 9030 | 9280 |
| Example 9 | 8900 | 9000 |
| Example 10 | 8910 | 7800 |
| Example 11 | 8800 | 5400 |
| Example 12 | 8840 | 6730 |
| Example 13 | 8930 | 9040 |
| Comparative | 8900 | 3740 |
| Example 3 | | |

### INDUSTRIAL APPLICABILITY

The resist underlayer film-forming compositions according to the present invention have no change in the molecular weight of the polymer even after the lapse of a certain amount of time and thereby attain excellent storage stability.

1. A resist underlayer film-forming composition comprising a polymer containing a disulfide bond, a radical trapping agent, and a solvent.

2. The resist underlayer film-forming composition according to claim 1, wherein the polymer is a reaction product of:
a bi- or higher-functional compound (A) having at least one disulfide bond, and
a bi- or higher-functional compound (B) different from compound (A).

3. The resist underlayer film-forming composition according to claim 1, wherein the radical trapping agent is a compound (T) having a ring structure or a thioether structure.

4. The resist underlayer film-forming composition according to claim 3, wherein the ring structure is a C6-C40 aromatic ring structure or a 2,2,6,6-tetramethylpiperidine structure.

5. The resist underlayer film-forming composition according to claim 3, wherein compound (T) contains a hydroxy group, a C1-C10 alkyl group or a C1-C20 alkoxy group.

6. The resist underlayer film-forming composition according to claim 2, wherein bi- or higher-functional compound (B) contains a C6-C40 aromatic ring structure or a heterocyclic structure.

7. The resist underlayer film-forming composition according to claim 1, further comprising a crosslinking catalyst.

8. The resist underlayer film-forming composition according to claim 1, further comprising a crosslinking agent.

9. A resist underlayer film, which is a calcined product of a coating film comprising the resist underlayer film-forming composition according to claim 1.

10. A method for producing a resist-patterned substrate for use in manufacturing of a semiconductor device, comprising the steps of:
applying the resist underlayer film-forming composition according to claim 1 onto a semiconductor substrate and baking the applied composition to form a resist underlayer film,
applying a resist onto the resist underlayer film and baking the applied resist to form a resist film,
exposing the semiconductor substrate coated with the resist underlayer film and the resist, and
developing the exposed resist film.

11. A method for manufacturing a semiconductor device, comprising the steps of:
forming on a semiconductor substrate a resist underlayer film from the resist underlayer film-forming composition according to claim 1,
forming a resist film on the resist underlayer film,
exposing the resist film,
developing the exposed resist film into a resist pattern,
etching the resist underlayer film through the resist pattern to form a patterned resist underlayer film, and
processing the semiconductor substrate through the patterned resist underlayer film.
